(19) United States
(12) Patent Application Publication
(10) Pub. No.: US 2019/0198536 A1
(43) Pub. Date: Jun. 27, 2019

(54) Image Sensor and Forming Method Thereof

(71) Applicant: Huaian Imaging Device Manufacturer Corporation, Huaian (CN)

(72) Inventors: Huan Wang, Huaian (CN); Zhiwei Li, Huaian (CN); Rende Huang, Huaian (CN)

(21) Appl. No.: 16/111,097

(22) Filed: Aug. 23, 2018

(30) Foreign Application Priority Data
Dec. 22, 2017 (CN) 201711405000.X

(51) Int. Cl. H01L 27/146

(52) U.S. Cl. CPC H01L 27/1462; H01L 27/14623; H01L 27/14685; H01L 27/14645; H01L 27/14627; H01L 27/1464; H01L 27/14621

(57) ABSTRACT

The present disclosure discloses a low cross talk image sensor and a forming method thereof. The image sensor includes photoelectric diodes; color filter lenses over the photodiodes, barrier structures are formed between two adjacent color filter lenses, and micro lenses. The refractive index of barrier structures is smaller than the refractive index of the color filter lenses.

### CROSS REFERENCES TO RELATED APPLICATIONS

This application claims the benefit of priority to Chinese Patent Application No. CN201711405000.X, entitled “Image Sensor and Forming Method Thereof”, filed with SIPO on Dec. 22, 2017, the contents of which are incorporated herein by reference in its entirety.

### TECHNICAL FIELD

The present disclosure relates to the technical field of semiconductor devices, and in particular, to an image sensor and a forming method thereof.

### BACKGROUND

A semiconductor image sensor is a semiconductor device for converting optical image signals to electrical image signals. A CMOS (Complementary Metal Oxide Semiconductor) image sensors are solid-state image sensors which have been developed in past decades rapidly, for their obvious advantages such as that in an image sensor, the sensor portion and the control circuit portion can be integrated in a same chip, the CMOS image sensors have small sizes, they are low in power consumption and can be made with low cost,. Compared to the traditional CCD (Charge Coupled Device) image sensor, the CMOS image sensors have more advantages and are naturally more popular.

An existing CMOS image sensor includes a photoelectric part for converting an optical signal to electrons, such as a photoelectric diode formed in a silicon substrate. In addition, a dielectric layer is also formed on a surface of the silicon substrate over the photoelectric diode, a metal interconnection layer is formed in the dielectric layer, and the metal interconnection layer is used for electrically connecting the photoelectric diode and a peripheral circuit. For the above described CMOS image sensor, the front surface is the one having the dielectric layer and the metal interconnection layer, and the back surface is the other opposing surface. Based on light irradiation direction, the CMOS image sensors can be classified into front-side illumination (FSI) CMOS image sensors or back-side illumination (BSI) CMOS image sensors.

For the front-side illumination CMOS image sensor, light is incident on the front surface of the CMOS image sensor. Incident light passes through a number of dielectric layers and metal interconnection layers in the light path before illuminating on the photoelectric diode, the amount of light absorbed by the photoelectric diode may be limited, resulting in lower quantum efficiency. For the back-side illumination CMOS image sensor, light is incident on the photoelectric diode from the back surface, thereby similar loss of light is eliminated, improving the photon-to-electron conversion efficiency.

For existing back-side illumination CMOS image sensors, there is serious crosstalk problem from lateral scattering, resulting in poor photoelectric conversion accuracy and stability. A problem needs a solution is how to reduce optical cross talk and improve photoelectric conversion accuracy and stability for aback-side illumination CMOS image sensors.

### SUMMARY

The present disclosure provides an image sensor and forming method thereof.

The image sensor comprises: a substrate divided into a plurality of first zones and a plurality of second zones; a plurality of photoelectric diodes patterned in a sensor layer on a surface of the substrate, wherein the plurality of photoelectric diodes each is arranged overlapping one of the plurality of first zones; an isolation structure disposed on the sensor layer; a plurality of color filter lenses disposed on the first isolation layer and aligned to the plurality of photoelectric diodes; a plurality of barrier structures each disposed between two adjacent color filter lenses of the plurality of color filter lenses, wherein the plurality of barrier structures align to the plurality of second zones; and a plurality of micro lenses each on arranged on one of the plurality of color filter lens; wherein a refractive index of the plurality of barrier structures is smaller than a refractive index of the plurality of color filter lenses.

Optionally, the refractive index of the barrier layer is in a range from 1.2 to 1.65.

Optionally, a material of the plurality of barrier structures comprises: SiO₂, MgF₂, Al₂O₃ or Ti₃O₅.

Optionally, the plurality of color filter lenses comprises red color filter lenses, green color filter lenses or blue color filter lenses; wherein the isolation structure comprises: a first isolation layer disposed on the sensor layer and a second isolation layer disposed on the first isolation layer; wherein a metal grid is patterned in the second isolation layer aligning to the plurality of barrier structures.

The present disclosure further provides a method of forming an image sensor, comprising: providing a substrate; forming a sensor layer on a surface of the substrate, patterning a plurality of photoelectric diodes in the sensor layer; forming an isolation structure on the sensor layer; forming a plurality of color filter lenses on the isolation structure aligned to the plurality of photoelectric diodes; forming a plurality of barrier structures on the isolation structure; wherein a refractive index of the barrier structures is smaller than a refractive index of the plurality of color filter lenses; and forming a micro lens structure on at least one of the plurality of color filter lenses.

Optionally, forming a plurality of barrier structures comprises: forming a trench between adjacent two of the plurality of color filter lenses, and filling trench with a barrier material.

Optionally, a refractive index of the barrier layer is in a range from 1.2 to 1.65.

Optionally, the barrier material comprises: SiO2, MgF2, Al2O3 or Ti3O5; and wherein a forming process of the barrier structures comprises: a chemical vapor deposition process or a physical vapor deposition process.

Optionally, the plurality of color filter lenses comprises red color filter lenses, green color filter lenses or blue color filter lenses.

Optionally, the isolation structure comprises: the isolation structure comprises: a first isolation layer disposed on the sensor layer and a second isolation layer disposed on the first isolation layer.

Optionally, the method further comprises forming a metal grid under the plurality of barrier structures.

### BRIEF DESCRIPTION OF THE DRAWINGS

FIG. 1 is a schematic diagram of a conventional back-side illumination CMOS image sensor.

FIG. 2 to FIG. 8 are schematic diagrams of fabrication steps in forming an image sensor of according to one embodiment of the present disclosure.

### DETAILED DESCRIPTION OF THE PREFERRED EMBODIMENTS

The foregoing objectives, features, and advantages of the present disclosure will become more apparent from the following detailed description of specific embodiments of the disclosure in conjunction with the accompanying drawings. In the detailed description of the embodiments of the present disclosure, for convenience of description, the schematic diagram will be partially enlarged not according to an ordinary ratio, and the schematic diagram is only an example, which should not limit the protection scope of the present disclosure. In addition, three-dimensional space dimensions of length, width, and depth should be comprised in actual production.

It should be noted that the illustration provided in the present embodiment merely illustrates the basic concept of the present disclosure by way of illustration. Although only components related to the present disclosure are shown in the illustration, the number, shape and size drawing of the components in actual implementation are not limited. The form, quantity and proportion of various components in actual implementation may be randomly changed, and the layout of the components may also be more complicated.

As described in the background, crosstalking in back-side illumination CMOS image sensors is serious.

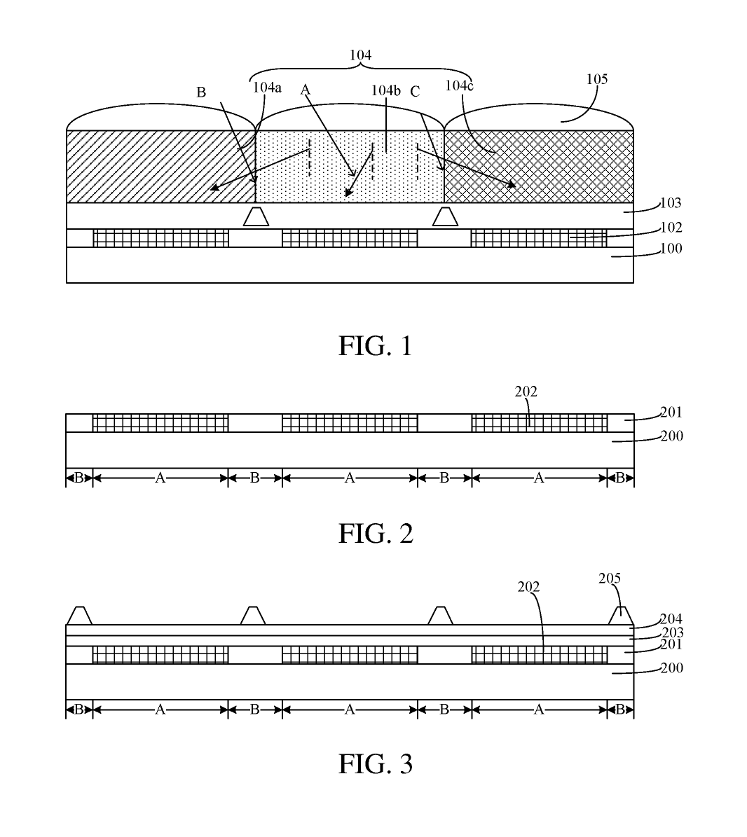

FIG. 1 is a structural schematic diagram of a conventional back-side illumination CMOS image sensor.

Referring to FIG. 1, a back-side illumination CMOS image sensor according to one embodiment includes: a substrate 100; a plurality of photoelectric diodes 102 disposed on a surface of the substrate 100; isolation layers 103 disposed on surfaces of the photoelectric diodes 102; a plurality of color filter lenses 104 disposed on surfaces of the isolation layers 103, wherein each color filter lens 104 corresponds to one photoelectric diode 102; and micro lenses 105 disposed on surfaces of the color filter lenses 104.

In the above back-side illumination CMOS image sensor, light coming from different incident angles within the view of each of the micro lenses 105 is focused into the underneath color filter lens 104 where photons of undesired wavelengths are filtered out, and monochromatic light corresponding to the color filter lenses 104 forms before the photoelectric diodes 102. The monochromatic light is absorbed by the underneath photoelectric diode 102, and excites electron-hole pairs, thereby implementing the photoelectric conversion.

Specifically, taking a color filter lens 104b as an example, light in different incident angles enters the color filter lens 104b; and the light in different angles comprises incident light A irradiated into the color filter lens 104b, incident light B irradiated on an interface between the color filter lens 104b and a color filter lens 104a, and incident light C irradiated on an interface between the color filter lens 104b and a color filter lens 104c. The incident light A can enter the range of the corresponding photoelectric diode 102 after passing through the color filter lens 104b so as to implement the photoelectric conversion within the corresponding photoelectric diode 102.

However, when the incident light B reaches the interface between the color filter lens 104b and the color filter lens 104a, may easily enter the adjacent color filter lens 104a. Therefore, the incident light B is not completely filtered by the color filter lens 104b. After the unfiltered incident light B enters the color filter lens 104a from the color filter lens 104b, the incident light B is further filtered by the color filter lens 104a, and is finally irradiated on the photoelectric diode 102 underneath the color filter lens 104a, thereby resulting in a cross talk of the back-side illumination CMOS image sensor. Similarly, the incident light C easily enters the color filter lens 104c from 104b, is further filtered by the color filter lens 104c, and is then irradiated on the photoelectric diode 102 underneath the color filter lens 104c, thereby resulting in across talk of the back-side illumination CMOS image sensor.

In order to solve the cross talking problem, the present disclosure provides an image sensor and the sensor's forming method. The image sensor includes barrier layers, formed between the adjacent color filter lenses, the refractive index of the barrier layer material is smaller than the refractive index of the color filter lens material. The barrier layers can prevent unwanted passing of incident light into adjacent color filter lens to reduce or eliminate cross talk.

A method of forming such an image sensor is described in details in the following texts.

FIG. 2 to FIG. 8 are schematic diagrams of fabrication steps in forming an image sensor of according to one embodiment of the present disclosure.

Referring to FIG. 2, a substrate 200 is provided; a sensor layer 201 is formed on a surface of the substrate 200, the sensor layer 201 is divided in zones aligned with the photodiodes. Zone one or A aligns with diodes and zone two or B aligns with the gap between adjacent photodiodes.

The substrate 200 comprises: a supporting substrate (not shown), a dielectric layer (not shown) disposed on the surface of a supporting substrate, and an electric interconnection structure (not shown) disposed in the dielectric layer.

The method of forming the substrate 200 and the sensor layer 201 comprises: providing a semiconductor substrate (not shown); forming a sensor layer 201 in the semiconductor substrate, wherein the sensor layer 201 comprises a plurality of first zones A and second zones B between the adjacent first zones A along a direction parallel to a surface of the substrate, and the sensor layer 201 in the first zone A has a photoelectric diode 202; forming a dielectric layer on a first surface of the semiconductor substrate after the sensor layer 201 is formed, wherein the dielectric layer has an electric interconnection structure therein; forming a supporting substrate on a surface of the dielectric layer; thinning the semiconductor substrate from a second surface of the semiconductor substrate after the supporting substrate is formed until the sensor layer 201 is exposed, and the second surface is opposite to the first surface.

In the present embodiment, the semiconductor substrate is a silicon substrate.

In other embodiments, the semiconductor substrate can be a germanium substrate, a silicon carbide substrate, a germanium-silicon substrate, a silicon-on-insulator substrate or a germanium-on-insulator substrate, the semiconductor substrate is doped with P-type or N-type ions.

In the present embodiment, the image sensor is a back-side illumination CMOS image sensor and the sensor layer 201 is formed by a semiconductor substrate.

In the present embodiment, the semiconductor substrate is a silicon substrate, and the silicon substrate is doped with a P-type well area. The forming steps of the sensor layer 201 comprise: injecting N-type ions onto the first surface of the semiconductor substrate to form a plurality of N-type doping areas on the first surface of the semiconductor substrate, the N-type doping areas and the P-type well area form an initial sensor layer, a first surface of the initial sensor layer is the first surface of the semiconductor substrate, and the initial sensor layer has a second surface opposite to the first surface; the substrate 200 is formed on the first surface of the initial sensor layer; and, grinding the second surface of the initial sensor layer after the substrate 200 is formed until the N-type doping areas are exposed to form the sensor layer 201.

In other embodiments, when the silicon substrate is in an eigenstate, the P-type ions are injected from the first surface of the silicon substrate, to form the P-type well area on the first surface of the silicon substrate; the N-type ions are injected onto the first surface of the silicon substrate to form a plurality of N-type doping areas in the P-type well area, the N-type doping areas and the P-type well area form the initial sensor layer, a first surface of the initial sensor layer is the first surface of the semiconductor substrate, and the initial sensor layer also has a second surface opposite to the first surface; the substrate is formed on the first surface of the initial sensor layer; and after the substrate is formed, the second surface of the initial sensor layer is ground until the N-type doping areas are exposed to form a sensor layer.

The sensor layer is patterned subsequently.

A process for planarizing the second surface of the initial sensor layer can be chemical mechanical planarization (CMP) process.

A photoelectric diode 202 is formed between the P-type well area and one N-type doping area; and the sensor layer 201 comprises a plurality of N-type doping areas therein, therefore the sensor layer 201 comprises a plurality of photoelectric diodes 202.

A material of the dielectric layer maybe silicon oxide; and a forming process of the dielectric layer can be a chemical vapor deposition (CVD) process or a physical vapor deposition (PVD) process. The dielectric layer has an electric interconnection structure, and the electric interconnection structure can realize the required electric connection between the image sensor and an external circuit.

A material of the supporting substrate is a semiconductor material, and a forming process of the supporting substrate can be a selective epitaxial deposition process.

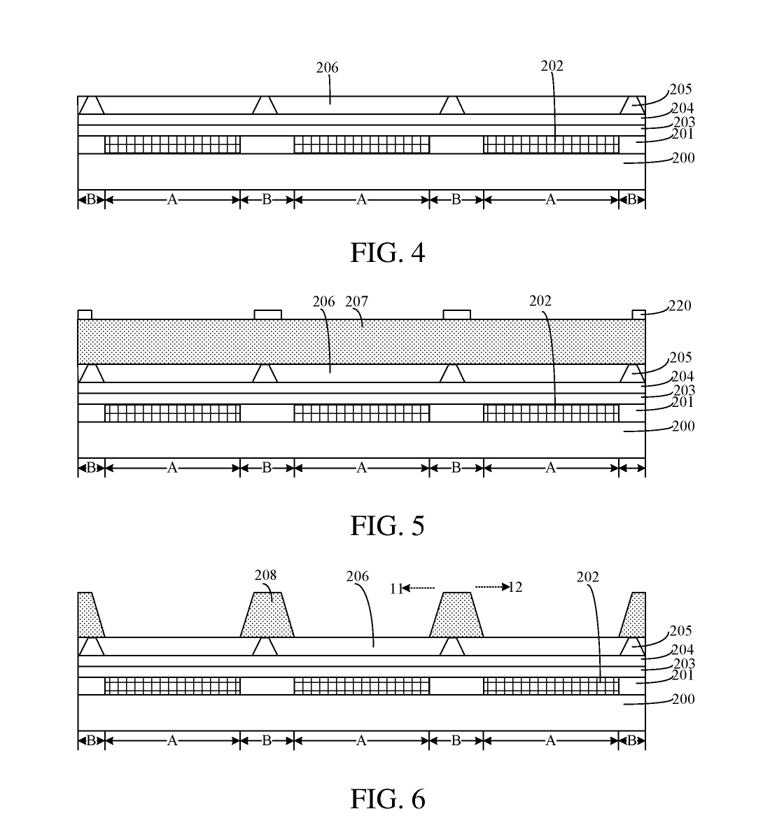

After the sensor layer 201 is formed, the forming method comprises: forming an isolation structure on the surface of the sensor layer 201. In the present embodiment, the isolation structure comprises: a first isolation layer disposed on a surface of the sensor layer 201 and a plurality of second isolation layers disposed on a surface of the first isolation layer and separated from one another. The specific forming steps of the isolation structure are illustrated in FIG. 3 to FIG. 4.

Referring to FIG. 3, a passivation layer 203 is formed on a surface of the sensor layer 201; a first isolation layer 204 is formed on the passivation layer 203; and a metal grid 205 is formed on a surface of the first isolation layer 204 in the second zone B.

In the present embodiment, after the sensor layer 201 is formed, and prior to the forming of the first isolation layer 204, the forming method further comprises: the passivation layer 203 is formed on a surface of the sensor layer 201. In other embodiments, the first isolation layer is directly formed on the surface of the sensor layer.

A forming process of the passivation layer 203 can be a chemical vapor deposition process. A material of the passivation layer 203 can be silicon nitride, and the passivation layer 203 is used for protecting the sensor layer 201 when the first isolation layer 204 is subsequently formed.

A material of the first isolation layer 204 comprises: silicon oxide, silicon nitride or silicon oxynitride. A forming process of the first isolation layer 204 comprises a chemical vapor deposition process or a physical vapor deposition process. The first isolation layer 204 is used for isolating the sensor layer 201 from a color filter lenses formed subsequently.

In the present embodiment, after the first isolation layer 204 is formed, and prior to the formation of the second isolation layer, a metal grid 205 is formed. In other embodiments, after the first isolation layer is formed, the second isolation layer is directly formed on a surface of the first isolation layer without forming the metal grid.

In the present embodiment, forming steps of the metal grid 205 comprise: forming a metal grid membrane on the first isolation layer 204, the metal grid membrane has a second patterning layer, which exposes a top surface of the metal grid membrane in the first zone A; and etching the metal grid membrane with the second patterning layer being used as a mask until the top surface of the first isolation layer 204 is exposed, thereby forming the metal grid 205.

A material of the metal grid membrane is metal, and correspondingly, a material of the metal grid 205 is metal. In the present embodiment, the material of the metal grid membrane is aluminum, and correspondingly, the material of the metal grid 205 is aluminum. In other embodiments, the material of the metal grid membrane is aluminum doped with a little copper; and correspondingly, the material of the metal grid is the combination of aluminum and copper.

In the present embodiment, a forming process of the metal grid membrane is a physical vapor deposition process. In other embodiments, a formation process of the metal grid membrane is a chemical vapor deposition process.

The second lithographic layer is used for defining a pattern and a position of the metal grid 205.

In the present embodiment, the second lithographic layer is an exposed patterning photoresist layer. The second patterning layer exposes a surface of the metal grid membrane in the first zone A, and then the metal grid 205 formed subsequently is disposed on a surface of the first isolation layer 204 in the second zone B, so that the formed metal grid 205 sufficiently utilizes a space between the adjacent photoelectric diodes 202 without increasing the size of the formed image sensor.

Functions of the metal grid 205 comprise: on one hand, the metal grid 205 can reflect the incident light; on the other hand, the metal grid 205 can prevent the incident light from entering the adjacent color filter lens from one color filter lens, and the incident light can return onto the photoelectric diode 202 corresponding to the color filter lens, so that the quantum loss can be avoided while the cross talk is avoided, thereby improving the photoelectric conversion efficiency.

Referring to FIG. 4, the second isolation layer 206 is formed on a surface of the first isolation layer 204 and on a side wall of the metal grid 205, and the top of the second isolation layer 206 exposes a top surface of the metal grid 205.

Forming steps of the second isolation layer 206 comprise: forming a second isolation membrane on the surface of the first isolation layer 204 and on the side wall and the top surface of the metal grid 205; flattening the second isolation membrane until the top surface of the metal grid 205 is exposed to form the second isolation layer 206.

A material of the second isolation membrane comprises silicon oxide, silicon nitride or silicon oxynitride, and correspondingly, a material of the second isolation layer 206 comprises silicon oxide, silicon nitride or silicon oxynitride.

A forming process of the second isolation membrane comprises a chemical vapor deposition process. A process for flattening the second isolation membrane comprises: a chemical mechanical grinding process, and the second isolation layer 206 is used for isolating the sensor layer 201 and the color filter lens formed subsequently.

Referring to FIG. 5, a barrier film 207 is formed on a surface of the second isolation layer 206; and a first patterning layer 220 is formed on a surface of the barrier film 207 in the second zone B.

A material of the barrier film 207 is a low refractive index material. In the present embodiment, the material of the barrier film 207 is SiO₂ In other embodiments, the material of the barrier film may be MgF₂, Al₂O₃ or Ti₃O₅.

In the present embodiment, the reason for selecting SiO₂ as the material of the barrier film 207 lies in that SiO₂ does not act with water or halogens except for fluorine and hydrogen fluoride as well as sulfuric acid, nitric acid, perchloric acid(except for hot thick phosphoric acid), the chemical property of SiO₂ is relatively stable, so that the performance of the SiO₂ serving as the barrier film 207 is relatively stable. The barrier film 207 is used for subsequently forming the barrier layer, therefore, the performance of the barrier layer is stable, the capacity of the barrier layer for blocking the passing of the incident light is relatively high, and the incident light can be prevented from entering one color filter lens adjacent to a color filter lens from which the incident light enters to cause crosstalk.

The refractive index of a material of the barrier film 207 is 1.2 to 1.65. The barrier film 207 is used for subsequently forming the barrier layer; therefore, the refractive index of the material of the barrier film 207 determines the refractive index of the barrier layer formed subsequently.

A forming process of the barrier film 207 comprises: a chemical vapor deposition process or a physical vapor deposition process.

The first patterning layer 220 is used for defining a pattern and a position of the subsequent barrier layer.

In the present embodiment, the first patterning layer 220 is an exposed patterning photoresist layer. The first patterning layer 220 is disposed on a surface of the barrier film 207 in the second zone B, the barrier layer formed subsequently is disposed in the second zone B, and the formed barrier layer sufficiently utilizes the space between the adjacent photoelectric diodes 202 without increasing the size of the formed image sensor.

Please refer to FIG. 6, the first patterning layer 220 (as shown in FIG. 5) is taken as a mask to etch the barrier film 207 (as shown in FIG. 5) until the second isolation layer 206 is exposed, and the barrier layer 208 is formed in the second zone B; and after the barrier layer 208 is formed, the first patterning layer 220 is removed.

A process for etching the barrier film 207 by using the first patterning layer 220 as the mask comprises: one or a combination of a dry-method etching process and a wet-method etching process.

The first patterning layer 220 is used for defining a pattern and a position of the barrier layer 208. Since the first lithographic layer 220 is disposed in the second zone B, the formed barrier layer 208 is disposed in the second zone B.

Moreover, the barrier film 207 is used for forming the barrier layer 208. In the present embodiment, the material of the barrier layer 208 is SiO₂. In other embodiments, the material of the barrier layer comprises: MgF₂, Al₂O₃ or Ti₃O₅.

Moreover, the refractive index of the material of the barrier layer 208 is 1.2 to 1.65. The barrier layer 208 comprises a first side 11 and a second side 12 opposite to each other in a direction parallel to a surface of the substrate 200, and the first side 11 and the second side 12 of the barrier layer 208 subsequently cover a side wall of the color filter lens.

The significance of selecting the material of the barrier layer 208 to have such refractive index is illustrated by taking incident light irradiated on an interface between the barrier layer 208 and the color filter lens at the first side 11 of the barrier layer 208 as an example. If the refractive index of the barrier layer 208 is smaller than 1.2, the incident light irradiated on the interface between the barrier layer 208 and the color filter lens at the first side 11 of the barrier layer 208 still easily penetrates through the barrier layer 208, then enters the color filter lens at the first side 11 of the barrier layer 208, and finally irradiates on the photoelectric diode 202 corresponding to the color filter lens at the first side 11 of the barrier layer 208 after being filtered by the color filter lens at the first side 11 of the barrier layer 208, thereby leading to the cross talk of the back-side illumination CMOS image sensor and influencing accuracy and stability of the photoelectric conversion. If the refractive index of the material of the barrier layer 208 is greater than 1.65, the light which is subsequently irradiated on the interface between the barrier layer 208 and the first side 11 of the barrier layer 208 easily generates total reflection, the total reflection light is easily irradiated on the photoelectric diode 202 corresponding to the color filter lens at the second side 12 of the barrier layer 208 after being filtered by the color filter lens, therefore, optical cross talk also likely occurs, thereby influencing accuracy and stability of the photoelectric conversion.

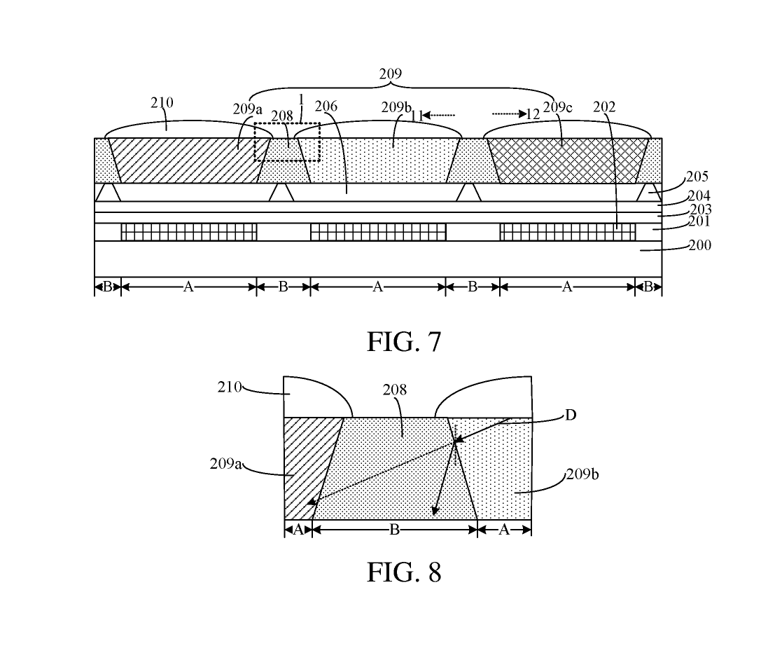

Referring to FIG. 7 and FIG. 8, FIG. 8 is an enlarged view of area 1 of FIG. 7. Two color filter lenses 209a and 209b are formed on the surface of the second isolation layer 206 in the first zone A, and the color filter lenses 209a and 209b cover both side walls of the barrier layer 208; and a micro lens structure 210 is formed on the surface of each color filter lens 209a or 209b.

Both the color filter lenses 209 and the photoelectric diodes 202 are disposed aligned to the first zone of the sensor layer 201.

The color filter lenses 209 may be red color filter lens 209a, green color filter lens 209b or blue color filter lens 209c. Moreover, color filter lenses 209 of one color are formed on a surface of the second isolation layer 206 on one photoelectric diode 202, and light entering the color filter lens 209 can be filtered by the color filter lenses 209 of one color, so that the incident light irradiated on the photoelectric diode 202 is monochromatic light.

The micro lens structure 210 is used for focusing image light, so that incident light passing through one micro lens structure 210 can be irradiated onto the photoelectric diode 202 under the micro lens structure 210.

Since the barrier layer 208 is provided between the adjacent color filter lenses 209, the barrier layer 208 can sufficiently prevent the incident light from entering an adjacent color filter lens 209 from a color filter lens 209, thereby avoiding the cross talk. Specifically, referring to FIG. 8, taking the green color filter lens 209b as an example, light D is irradiated on an interface between the green color filter lens 209b and the barrier layer 208 through the micro lens structure 210. If no barrier layer 208 is provided, the light D enters the red color filter lens 209a along a dotted line direction, and is finally irradiated onto the photoelectric diode 202 corresponding to the red color filter lens 209a after being filtered by the red color filter lens 209a, which likely cause the cross talk of the back-side illumination CMOS image sensor. If the barrier layer 208 is formed between the adjacent photoelectric diodes 202, and the refractive index of the barrier layer 208 is 1.2 to 1.65, the light D will be refracted along a solid line direction, and the light D will not enter the red color filter lens 209a; and therefore, the optical cross talk can be reduced, and the image sensor is accurate and stable in performance.

The present disclosure further provides a semiconductor structure formed by adopting the above method. Referring to FIG. 7, the semiconductor structure comprises:

a substrate 200;

a sensor layer 201 disposed on a surface of the substrate 200, wherein the sensor layer 201 comprises a plurality of first zones A and second zones B between the adjacent first zones A along a direction parallel to the surface of the substrate 200, and the sensor layer 201 in the first zone A has a photoelectric diode 202;

an isolation structure disposed on a surface of the sensor layer 201;

a color filter lens 209 disposed on a surface of the isolation structure in the first zone A;

a barrier layer 208 disposed on a surface of the isolation layer in the second zone B, the barrier layer 208 covers a side wall of the color filter lens 209, and a refractive index of a material of the barrier layer 208 is smaller than a refractive index of a material of the color filter lens 209; and

a lens structure 210 disposed on a surface of the color filter lens 209.

A refractive index of the barrier layer 208 is 1.2 to 1.65. The material of the barrier layer 208 comprises: SiO2, MgF2, Al2O3 or Ti3O5.

A surface of the isolation structure on one photoelectric diode 202 has one color filter lens 209, and the color filter lens 209 disposed on a surface of the isolation structure on one photoelectric diode 202 is a red color filter lens, a green color filter lens or a blue color filter lens.

The technical solution of the present disclosure has the following benefits:

In the image sensor provided in the present disclosure, light in different angles enters the color filter lens in a single pixel zone through a micro lens structure. Since the barrier layer is provided between the adjacent color filter lenses, and the refractive index of the barrier layer material is smaller than the refractive index of the color filter lens material, the barrier layer can prevent the light irradiated on a junction between the color filter lens and the barrier layer from entering the adjacent color filter lens, so that the incident light entering the color filter lens in the single pixel area can completely irradiate on the sensor layer corresponding to the pixel zone, thereby avoiding cross talk, and enabling the image sensor to be accurate and stable in performance

Although the present disclosure is disclosed as above, the present disclosure is not limited thereto. Various changes and modifications may be made by any person skilled in the art without departing from the spirit and scope of the present disclosure, and therefore the protection scope of the present disclosure shall be subjected to the scope defined by the claims.

What is claimed is:

1. An image sensor, comprising:
a substrate divided into a plurality of first zones and a plurality of second zones;
a plurality of photoelectric diodes patterned in a sensor layer on a surface of the substrate, wherein the plurality of photoelectric diodes each is arranged overlapping one of the plurality of first zones;
an isolation structure disposed on the sensor layer;
a plurality of color filter lenses disposed on the first isolation layer and aligned to the plurality of photoelectric diodes;
a plurality of barrier structures each disposed between two adjacent color filter lenses of the plurality of color filter lenses, wherein the plurality of barrier structures align to the plurality of second zones; and
a plurality of micro lenses each on arranged on one of the plurality of color filter lens;
wherein a refractive index of the plurality of barrier structures is smaller than a refractive index of the plurality of color filter lenses.

2. The image sensor according to claim 1, wherein the refractive index of the plurality of barrier structures is in a range from 1.2 to 1.65.

3. The image sensor according to claim 2, wherein a material of the plurality of barrier structures comprises: SiO2, MgF2, Al2O3 or Ti3O5.

4. The image sensor according to claim 1, wherein the plurality of color filter lenses comprises red color filter lenses, green color filter lenses or blue color filter lenses;
wherein the isolation structure comprises: a first isolation layer disposed on the sensor layer and a second isolation layer disposed on the first isolation layer; wherein a metal grid is patterned in the second isolation layer aligning to the plurality of barrier structures.

5. A method of forming an image sensor, comprising:
providing a substrate;
forming a sensor layer on a surface of the substrate;
patterning a plurality of photoelectric diodes in the sensor layer;
forming an isolation structure on the sensor layer;
forming a plurality of color filter lenses on the isolation structure aligned to the plurality of photoelectric diodes;
forming a plurality of barrier structures on the isolation structure;
wherein a refractive index of the barrier structures is smaller than a refractive index of the plurality of color filter lenses; and
forming a micro lens structure on at least one of the plurality of color filter lenses.

6. The method of forming the image sensor according to claim 5, wherein forming a plurality of barrier structures comprises: forming a trench between adjacent two of the plurality of color filter lenses, and filling trench with a barrier material.

7. The method of forming the image sensor according to claim 5, wherein a refractive index of the barrier layer is in a range from 1.2 to 1.65.

8. The method of forming the image sensor according to claim 7, wherein the barrier material comprises: SiO2, MgF2, Al2O3 or Ti3O5; and wherein a forming process of the barrier structures comprises: a chemical vapor deposition process or a physical vapor deposition process.

9. The method of forming the image sensor according to claim 5, wherein the plurality of color filter lenses comprises red color filter lenses, green color filter lenses or blue color filter lenses.

10. The method of forming the image sensor according to claim 5, wherein the isolation structure comprises: a first isolation layer disposed on the sensor layer and a second isolation layer disposed on the first isolation layer.

11. The method of forming the image sensor according to claim 5, further comprising: forming a metal grid under the plurality of barrier structures.
